(19) United States
(12) Patent Application Publication
(10) Pub. No.: US 2017/0338291 A1
(43) Pub. Date: Nov. 23, 2017

(54) DISPLAY DEVICE AND MANUFACTURING METHOD OF THE SAME

(71) Applicant: JAPAN DISPLAY INC., TOKYO (JP)

(72) Inventor: YOSHINORI ISHII, TOKYO (JP)

(21) Appl. No.: 15/585,319

(22) Filed: May 3, 2017

(30) Foreign Application Priority Data
May 19, 2016 (JP) 2016-100495

(51) Int. Cl. H01L 27/32; G02F 1/1368; H01L 51/56; H01L 51/52

(52) U.S. Cl. CPC H01L 27/3244; H01L 51/5253; G02F 1/1368; H01L 51/56; G02F 2201/123; H01L 2227/32

(57) ABSTRACT

A flexible display device that is improved in a barrier property against moisture and is not deformed so much is realized. In an organic EL display device, TFT is formed in a first substrate and an organic EL layer is formed on the TFT. A protective layer is formed on the organic EL layer and a first base layer including an AlOₓ layer is formed outside the first substrate.

### CLAIM OF PRIORITY

The present application claims priority from Japanese Patent Application No. 2016-100495 filed on May 19, 2016, the content of which is hereby incorporated by reference into this application.

### BACKGROUND OF THE INVENTION

### (1) Field of the Invention

The present invention relates to display devices and in particular to a flexible display device in which a substrate can be bent.

### (2) Description of Related Art

Organic EL display devices and liquid crystal display devices can be flexibly bent when used by thinning the display devices. In these cases, substrates on which devices are to be formed are formed of a thin glass material or a thin resin material. Sheet-like thin substrates are difficult to throw into a manufacturing process. In case of glass substrates, for example, they are thrown into a process as thick substrates approximately 0.5 mm in thickness and after finishing, they are polished to form thin substrates to obtain flexible display devices.

When a substrate is formed of resin, a resin sheet is formed on a glass substrate to obtain a substrate of a display device and an array layer, a luminous layer, and the like are formed on the resin sheet. The glass substrate and the resin substrate are stripped by laser ablation or like to obtain a flexible display. This configuration is described in Japanese Patent Application Laid-Open No. 2004-349539.

In methods of stripping resin and a substrate by laser ablation, a glass substrate and a resin substrate are stripped from each other by ablating the interface between the substrates. Therefore, the resin substrate is damaged. If a resin substrate is damaged, external moisture and the like will become more prone to enter. Further, other problems, including a warp in a flexible display, will also arise due to stress or the like during stripping.

It is an object of the present invention to prevent warping of a display and suppress ingress of external moisture to embody a reliable flexible display, formed by, after finish, separating a glass substrate and a resin substrate from each other by laser ablation

### SUMMARY OF THE INVENTION

To achieve the above object, the present invention is typically configured as follows:

(1) According to one aspect of the present invention, provided is an organic EL display device obtained by forming TFT on a first substrate and forming an organic EL layer on the TFT. In this organic EL display device, a protective layer is formed on the organic EL layer and a first base layer is formed outside the first substrate.

(2) According to another aspect of the present invention, provided is a method for manufacturing an organic EL display device obtained by forming TFT on a first substrate and forming an organic EL layer on the TFT. This method for manufacturing an organic EL display device includes: forming a releasing layer on a glass substrate; forming a base layer on the releasing layer; forming a first substrate of polyimide on the base layer; forming the TFT in the first substrate; forming an organic EL layer on the TFT; forming a protective layer on the organic EL layer; and thereafter stripping the glass substrate, together with the releasing layer, from the first substrate.

(3) According to another aspect of the present invention, provided is a liquid crystal display device in which TFT and a pixel electrode are formed in a first substrate, a second substrate is disposed opposite to the first substrate, and a liquid crystal is sandwiched between the first substrate and the second substrate. In this liquid crystal display device, a first base layer is formed outside the first substrate.

(4) According to another aspect of the present invention, provided is a method for manufacturing a liquid crystal display device in which TFT and a pixel electrode are formed in a first substrate, a second substrate is disposed opposite to the first substrate, and a liquid crystal is sandwiched between the first substrate and the second substrate. This method for manufacturing a liquid crystal display device includes: forming a first releasing layer on a first glass substrate; forming a first base layer on the first releasing layer; forming a first substrate of polyimide on the first base layer; forming the TFT and the pixel electrode on the first substrate; forming a second releasing layer on a second glass substrate; forming a second base layer on the second releasing layer; forming a second substrate of polyimide on the second base layer; sealing a liquid crystal between the first substrate and the second substrate; thereafter, stripping the second glass substrate, together with the second releasing layer, from the second substrate; and stripping the first glass substrate, together with the first releasing layer, from the first substrate.

### BRIEF DESCRIPTION OF THE DRAWINGS

FIG. 1 is a plan view of an organic EL display device;

FIG. 2 is a sectional view taken along line A-A of FIG. 1;

FIG. 3A is a sectional view illustrating a method for manufacturing a flexible display device and a problem involved therein;

FIG. 3B is a sectional view illustrating a method for manufacturing a flexible display device and a problem involved therein;

FIG. 3C is a sectional view illustrating a method for manufacturing a flexible display device and a problem involved therein;

FIG. 4 is a plan view of a mother substrate;

FIG. 5 is a flowchart illustrating an example of a manufacturing process for an organic EL display device of the present invention;

FIG. 6A is a sectional view of a manufacturing process for an organic EL display device of the present invention;

FIG. 6B is a sectional view of a manufacturing process for an organic EL display device of the present invention;

FIG. 6C is a sectional view of a manufacturing process for an organic EL display device of the present invention;

FIG. 6D is a sectional view of a manufacturing process for an organic EL display device of the present invention;

FIG. 6E is a sectional view of a manufacturing process for an organic EL display device of the present invention;

FIG. 7 is a sectional view of an organic EL display device with a glass substrate bonded thereto;

FIG. 8 is a sectional view of an organic EL display device with a glass substrate stripped therefrom;

FIG. 9 is a graph indicating a relation between membrane stress of AlOₓ and moisture pressure in sputtering;

FIG. 10 is a graph indicating a relation between moisture pressure in sputtering and the refraction index of deposited AlOₓ;

FIG. 11 is a sectional view illustrating an example of the configuration of the outside of a TFT substrate;

FIG. 12 is a sectional view illustrating another example of the configuration of the outside of a TFT substrate;

FIG. 13 is a sectional view illustrating a further example of the configuration of the outside of a TFT substrate;

FIG. 14 is a plan view of a liquid crystal display device;

FIG. 15 is a sectional view taken along line B-B of FIG. 14;

FIG. 16 is a flowchart illustrating an example of a manufacturing process for a liquid crystal display device of the present invention;

FIG. 17 is a sectional view of a liquid crystal display device with a glass substrate bonded thereto; and

FIG. 18 is a sectional view of a liquid crystal display device with a glass substrate stripped therefrom.

### DETAILED DESCRIPTION OF THE PREFERRED EMBODIMENTS

Hereafter, a description will be given to the details of the present invention with reference to embodiments.

### First Embodiment

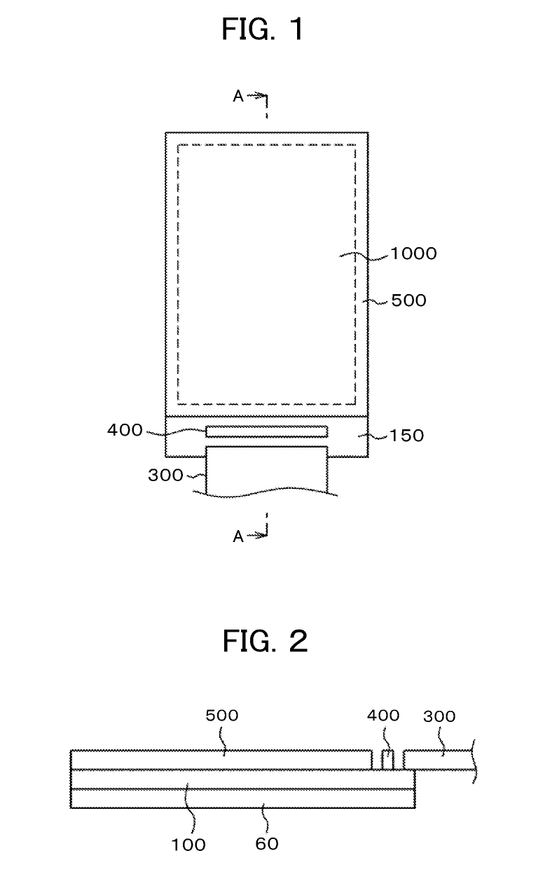

FIG. 1 is a plan view of an organic EL display device to which the present invention is applied. The organic EL display device of the present invention is a display device that can be flexibly bent. In FIG. 1, the organic EL display device includes a display area 1000 and a terminal part 150. The display area 1000 has a polarizing plate 500 bonded to the display area 1000 for reflection prevention. The terminal part 150 has a flexible wiring board 300 connected to the terminal part 150 for supplying power and signals to the organic EL display device. In addition, a driver IC 400 is connected to the terminal part 150 for driving the organic EL display device.

FIG. 2 is a sectional view taken along line A-A of FIG. 1. The display area and the terminal part are formed on a polyimide substrate 100. The polyimide substrate 100 is 10 to 20 μm in thickness and can be flexibly bent. Since the polyimide substrate 100 is thin, it is unstable in shape and may be insufficient in mechanical strength; therefore, a protective film 60 is stuck to the back thereof. The protective film 60 is formed of PET (polyethylene terephthalate) or acrylic resin and is approximately 0.1 mm in thickness.

In FIG. 2, an array layer having a luminous layer is formed on the polyimide substrate 100 and the polarizing plate 500 is disposed so as to cover the array layer. Since top emission-type organic EL display devices have a reflecting electrode, they reflect external light. The polarizing plate 500 is for preventing reflection of light from outside to make a screen viewable. FIG. 2 shows an organic EL display device without an opposite substrate.

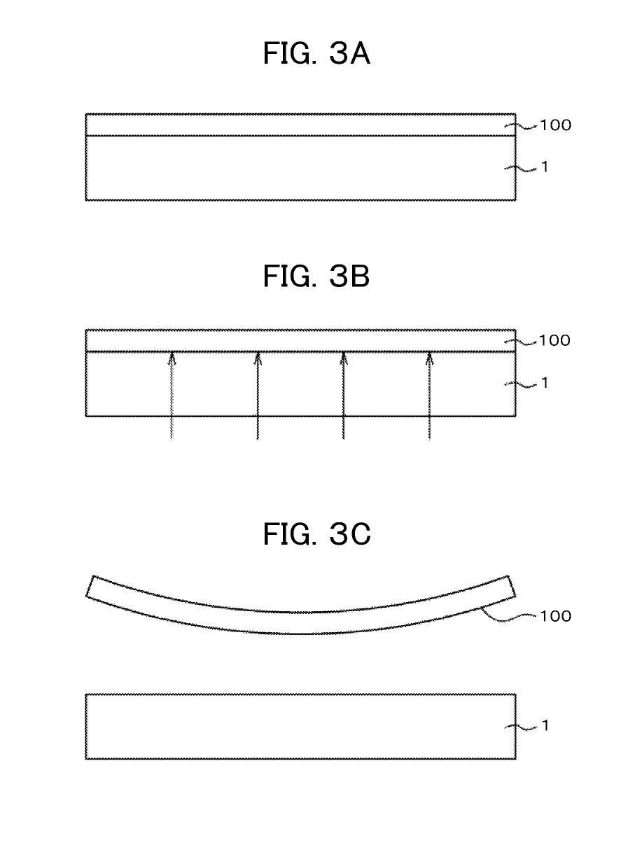

FIGS. 3A to 3C are sectional views illustrating a typical process for manufacturing such a flexible display as shown in FIGS. 1 and 2. In FIG. 3A, resin, for example, polyamic acid as a material of polyimide is applied onto a glass substrate 1 and dried and fired to obtain the resin substrate 100. A polyimide substrate is suitable for the resin substrate 100 because of its heat resistance and the like. The following description will be based on the assumption that the resin substrate 100 is a polyimide substrate but the resin substrate 100 in the present invention is not limited to a polyimide substrate.

The glass substrate 1 is sufficiently strong to go through a manufacturing process and is, for example, 0.5 mm in thickness. The polyimide substrate 100 formed on the glass substrate 1 is 10 to 20 μm in thickness. An array layer having a luminous layer, TFT, and the like is formed on the polyimide substrate 100. Since the polyimide substrate has TFT and the like formed therein, it is also referred to as TFT substrate 100.

Thereafter, as shown in FIG. 3B, a laser LA is focused on and applied to the interface between the polyimide substrate 100 and the glass substrate 1 to conduct laser ablation. Adhesive strength between the glass substrate 1 and the polyimide substrate 100 is thereby lessened and the polyimide substrate 100 and the glass substrate 1 are separated from each other.

FIG. 3C is a sectional view illustrating the glass substrate 1 with the polyimide substrate 100 having the array layer stripped therefrom. Stress from the manufacturing process and stress from laser ablation has been applied to the polyimide substrate 100 with the array layer formed therein; therefore, when the polyimide substrate is separated from the glass substrate 1, it is warped bent as shown in FIG. 3C, for example. Further, because of laser ablation, the interface between the polyimide substrate 100 and the glass has been roughened and external moisture and the like are prone to enter. Therefore, problems related to reliability are likely to occur. The present invention is intended to address this problem.

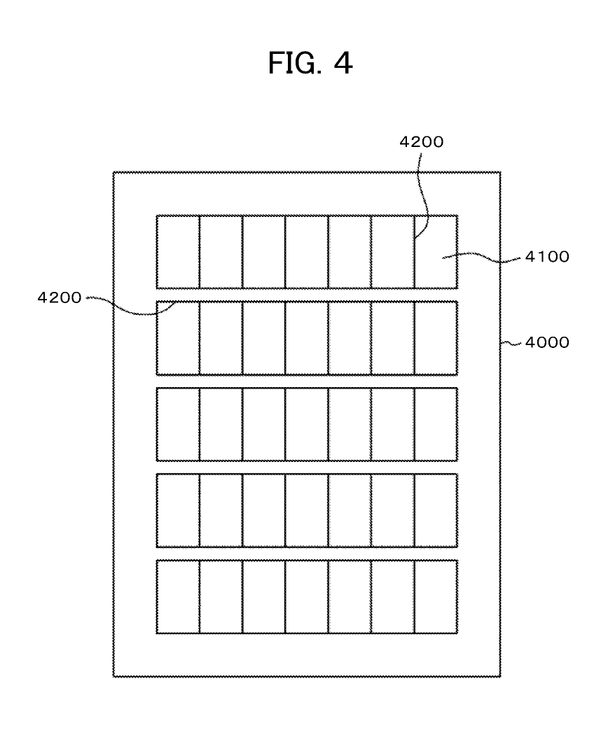

If organic EL display devices are manufactured one by one, efficiency will be degraded. To cope with this, a plurality of organic EL display devices is formed in a mother substrate and after finish, the mother substrate is separated into individual organic EL cells. FIG. 4 illustrates a case where 35 (=7×5) organic EL cells 4100 are formed in a mother substrate 4000. After finish, the mother substrate 4000 is separated into individual organic EL cells 4100 along break lines 4200. This separation is carried out by laser cutting, for example.

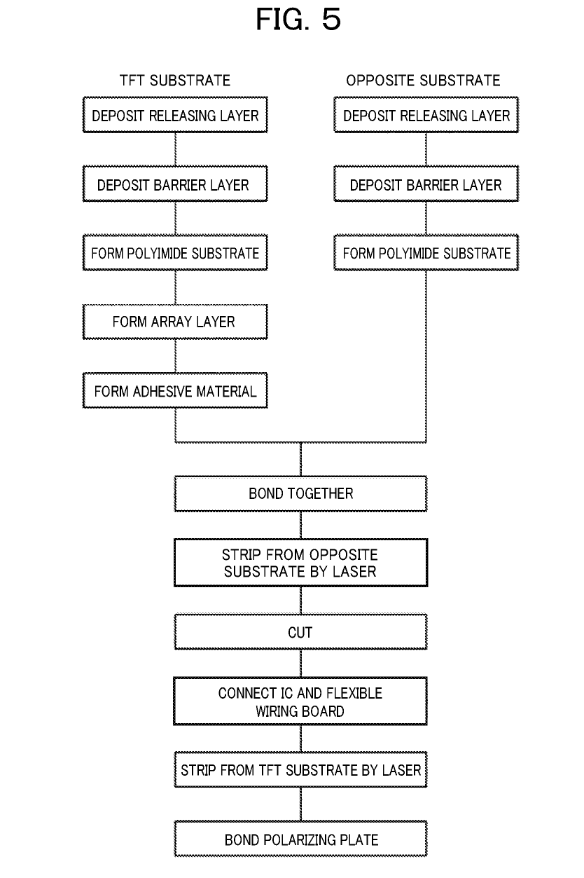

FIG. 5 illustrates an example of a manufacturing process for an organic EL display device. There are various methods for manufacturing organic EL display devices. In the method shown in FIG. 5, an opposite substrate is bonded to a TFT substrate with an array layer formed therein. In the example in FIG. 5, both the TFT substrate and the opposite substrate are formed of a polyimide substrate. That is, both the TFT substrate and the opposite substrate are formed by application to a glass substrate in the beginning and the glass substrate is thereafter separated.

In the example in FIG. 5, the TFT substrate and the opposite substrate are separately formed in the form of mother substrate. In the TFT substrate, after the formation of the polyimide substrate, an array layer including TFT, an organic EL layer, and the like is formed and an adhesive material is applied for bonding to the opposite substrate.

Thereafter, the mother TFT substrate and the mother opposite substrate are bonded together. First, the glass substrate on the opposite substrate side is stripped by laser ablation or the like as in the form of mother substrate. Thereafter, the mother substrates are separated into individual organic EL cell by laser cutting or the like and IC and a flexible wiring board are connected to each organic EL cell. Thereafter, each glass substrate is stripped from each TFT substrate by laser ablation. Thereafter, a polarizing plate is bonded to finish an organic EL display device.

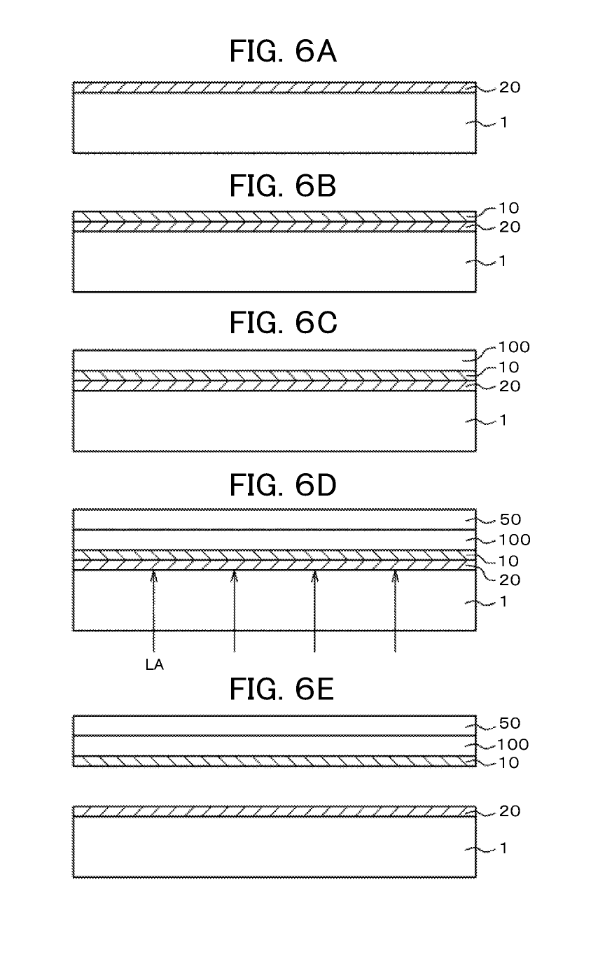

FIGS. 6A to 6E are process diagrams illustrating the features of the present invention. FIG. 6A shows how metal is formed as a releasing layer 20 on a glass substrate 1. The metal may be selected from among Ti, Ni, Cu, Fe, Ag, Au, Cr, Mo, W, and alloys containing these metals. When laser ablation is conducted later, this releasing layer 20 is stripped together with the glass substrate 1, from a polyimide substrate 100. The thickness of the metal is selected in correspondence with the wavelength of laser adopted for laser ablation. A preferable wavelength is YAG second harmonic (532 nm), second or third harmonic.

FIG. 6B illustrates how a base layer 10 of aluminum oxide AlOₓ (—AlOₓ may be Al₂O₃.) is formed on the releasing layer 20. Since AlOₓ is excellent in barrier property, even a thickness of approximately 30 nm to 80 nm allows a barrier function to be delivered. A more favorable film thickness is approximately 50 nm. FIG. 6C illustrates how the polyimide substrate 100 is formed on AlOₓ. The polyimide substrate 100 is formed by applying a liquid material to be polyimide using a slit coater or the like and thereafter drying and firing the material.

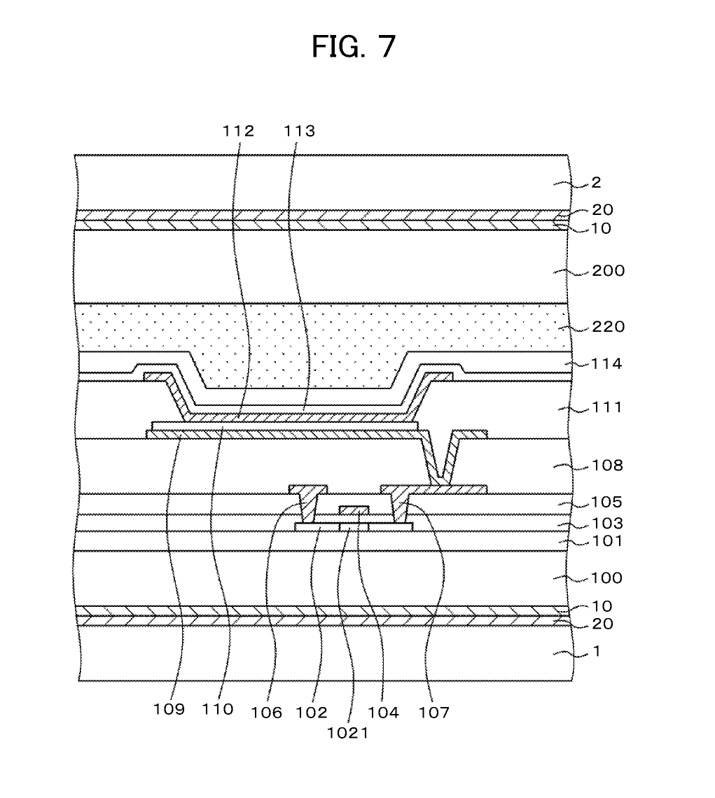

Further, as shown in FIG. 6D, an array layer 50 including TFT and an organic EL layer is formed on the polyimide substrate 100 to obtain an organic EL cell. There are cases where an opposite substrate is formed on the array layer 100, the substrate is omitted in the example shown in FIGS. 6A to 6E. FIG. 7 illustrates the configuration of the organic EL cell in detail. In FIG. 6D, the organic EL cell is represented by the TFT substrate 100 to make the drawing easier to understand.

Thereafter, as indicated by arrows LA in FIG. 6D, a laser LA is applied to the releasing layer 20 formed of metal and the releasing layer 20 and the base layer 10 are stripped from each other by laser ablation. FIG. 6E is a sectional view illustrating the polyimide substrate after the glass substrate 1 is stripped as mentioned above. At this time, laser ablation is conducted mainly at the releasing layer 20. At the same time, since the base layer 10 is present between the polyimide substrate 100 and the releasing layer 20, the polyimide substrate 100 is not damaged so much. This is one of the features of the present invention.

FIG. 7 is a sectional view of an organic EL display device before a glass substrate 1 is stripped by laser ablation. In FIG. 7, an opposite substrate 200 omitted in FIGS. 6A to 6E is placed. Depending on the type of the organic EL display device, the opposite substrate 200 may be not present.

FIG. 7 is a sectional view illustrating the configuration of the display area of a top emission-type organic EL display device of the present invention. In FIG. 7, a releasing layer 20 is formed on a glass substrate 1 and a base layer 10 of AlOₓ or the like is formed thereon. A polyimide substrate 100 is formed on the base layer 10. A base film 101 of silicon oxide SiOₓ (SiOₓ may be SiO₂), silicon nitride SiNₓ (SiNₓ may be Si₃N₄), or the like is formed on the polyimide substrate 100. The base film 101 is for preventing the ingress of moisture or the like from the polyimide substrate 100 side and thereby protecting TFT or an organic EL layer.

A semiconductor layer 102 is formed on the base film 101. The semiconductor layer 102 in FIG. 7 may be formed of oxide semiconductor or may be formed of Poly-Si. An example of the oxide semiconductor is a-IGZO (amorphous Indium Gallium Zinc Oxide). The oxide semiconductor is characterized by low leakage current. When the TFT in FIG. 7 is formed of Poly-Si semiconductor layer, the semiconductor layer 102 can be formed by, first, forming amorphous Si (a-Si) by CVD and converting it into Poly-Si by an excimer laser.

A gate insulating film 103 is formed of SiOₓ of TEOS (Tetraethoxysilane) using CVD such that the semiconductor layer 102 is covered. A gate electrode 104 is formed on the gate insulating film 103. Thereafter, the portion of the semiconductor layer 102 other than the portion thereof corresponding to the gate electrode 104 is turned into a conductive layer by ion implantation. The portion of the semiconductor layer 102 corresponding to the gate electrode 104 provides a channel part 1021.

An interlayer insulating film 105 is formed of SiNₓ by CVD such that the gate electrode 104 is covered. Thereafter, through holes are formed in the interlayer insulating film 105 and the gate insulating film 103 and a drain electrode 106 and a source electrode 107 are connected. In the example shown in FIG. 7, an organic passivation film 108 is formed such that the drain electrode 106, the source electrode 107, and the interlayer insulating film 105 are covered. Since the organic passivation film 108 also functions as a planarization film, it is formed so thick as 2 to 3 μm. The organic passivation film 108 is formed of acrylic resin, for example.

A reflecting electrode 109 is formed on the organic passivation film 108 and a lower electrode 110 providing a positive pole is formed on the reflecting electrode 109 of a transparent conductive film of ITO or the like. The reflecting electrode 109 is formed of an Al alloy high in reflectance. The reflecting electrode 109 is connected with the source electrode 107 of the TFT via a through hole formed in the organic passivation film 108.

A bank 111 of acryl or the like is formed on the periphery of the lower electrode 110. A purpose of forming the bank 111 is to prevent an organic EL layer 112 including a luminous layer and an upper electrode 113 to be formed next from being brought into faulty electrical continuity due to step disconnection. The bank 111 is formed by coating the entire surface with such transparent resin as acrylic resin and forming a hole in a portion corresponding to the lower electrode 110 to take light out of the organic EL layer.

In FIG. 7, the organic EL layer 112 is formed on the lower electrode 110. The organic EL layer 112 is formed of, for example, an electron injection layer, an electron transport layer, a luminous layer, a hole transport layer, a hole injection layer, or the like. The upper conductive layer 113 as a cathode is formed on the organic EL layer 112. The upper conductive layer 113 may be formed of IZO (Indium Zinc Oxide), ITO (Indium Tin Oxide), or the like as a transparent conductive film or may be formed of a thin film of such metal as silver.

Thereafter, a protective layer 114 is formed of SiNₓ on the upper electrode 113 using CVD for prevention of ingress of moisture from the upper electrode 113 side. Since the organic EL layer 112 is weak to heat, the CVD for forming the protective layer 114 is conducted at as low a temperature as approximately 100° C. An adhesive material is formed on the protective layer for bonding an opposite substrate.

As illustrated in FIG. 5, meanwhile, the opposite substrate 200 is formed aside from the TFT substrate 100. The opposite substrate 200 is formed similarly to the TFT substrate 100 side. More specific description will be given. A releasing layer 20 is formed on a second glass substrate 2 and a base layer 10 is formed on the releasing layer 20 of AlOₓ or the like. A polyimide material is applied to the base layer 10 by a slit coater or the like and dried and fired to form the opposite substrate 200 of polyimide. The thus formed opposite substrate 200 is bonded using the adhesive material 220 formed on the TFT substrate 100 side.

In this case, since the base layer 10 has been formed on the opposite substrate 200, the organic EL layer 112 formed on the TFT substrate 100 side is protected against external moisture and the like. In cases where a white organic EL layer is used for the organic EL layer 112, a color filter is required. In general, a color filter is formed on the opposite substrate 200 side.

To make a flexible display of the thus formed organic EL display device, it is necessary to strip off the first glass substrate 1 and the second glass substrate 2. This stripping is carried out by laser ablation in which a laser LA is applied to the releasing layer 20 as shown in FIG. 6D. When laser ablation is applied to the releasing layer 20, adhesive strength between the releasing layer 20 and the base layer 10 is lessened and the glass substrate 1 can be easily stripped off. This is also applicable to the second glass substrate 2 on the opposite substrate 200 side.

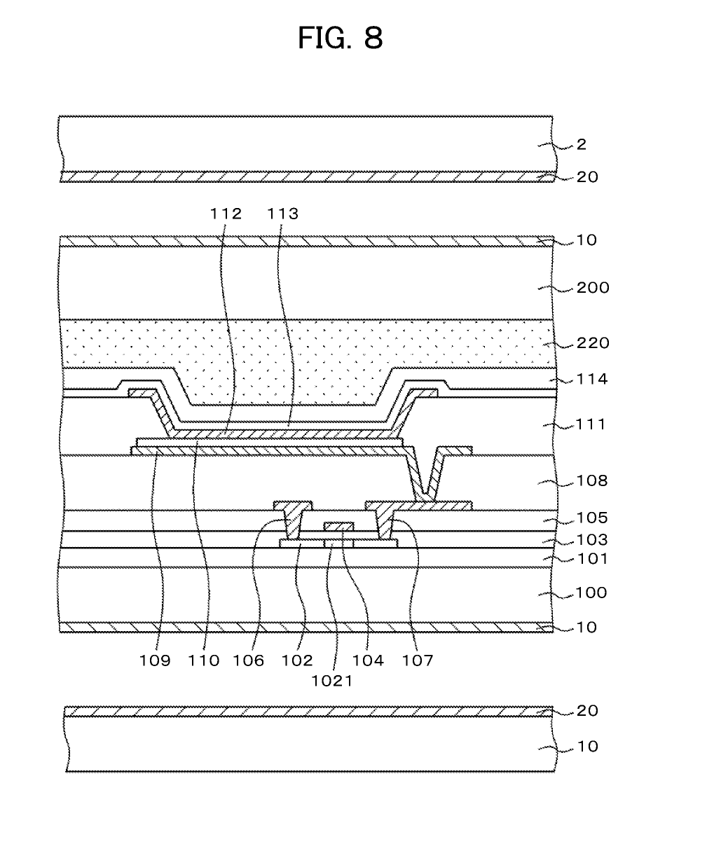

After the first glass substrate 1 and the second glass substrate 2 are stripped off, as shown in FIG. 8, the organic EL display device is very thin. In addition, the TFT substrate 100 side and the opposite substrate 200 side are different from each other in layer structure; therefore, as shown in FIG. 3C, the organic EL display device is prone to warp. To cope with this, for example, AlOₓ can be used for the base layer 10. When AlOₓ is used, membrane stress can be controlled by a manufacturing method and a warp in the flexible display can be thereby prevented.

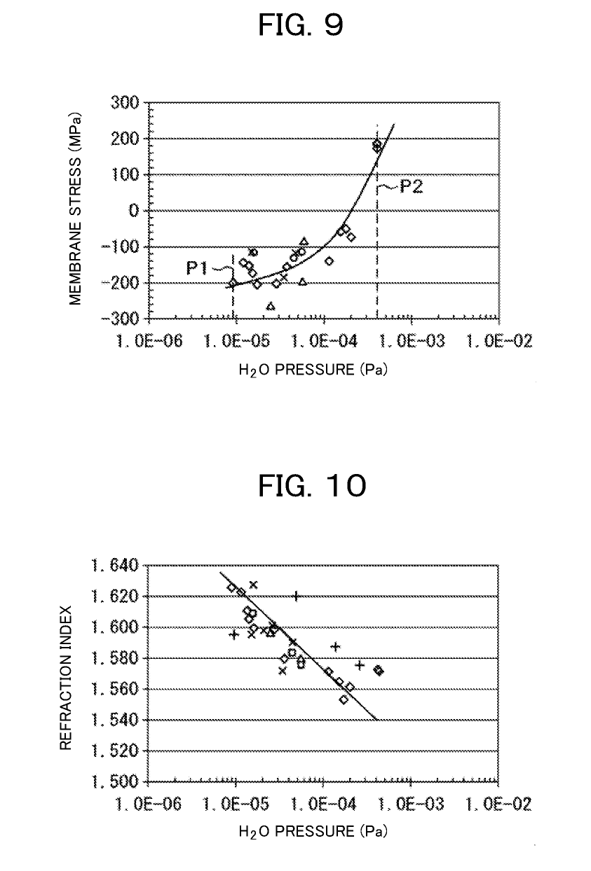

That is, AlOₓ is generally formed by sputtering and the sign of membrane stress is changed according to moisture pressure during sputtering. FIG. 9 is a graph indicating a relation between moisture pressure during sputtering and the membrane stress of a formed AlOₓ film. In FIG. 9, the horizontal axis represents moisture pressure during sputtering and the vertical axis represents the membrane stress of a formed AlOₓ film. As indicated in FIG. 9, the sign of membrane stress is changed from negative to positive with increase in moisture pressure.

In FIG. 9, when the moisture pressure is approximately 2×10⁻⁴ Pa, the membrane stress is zeroed. That is, a base layer having zero membrane stress can be formed by adopting a film obtained by sputtering at a moisture pressure of approximately 2×10⁻⁴ Pa. Meanwhile, when it is desired to use AlOₓ to control a warp in an entire sheet-like organic EL display device, it can be fabricated such that the membrane stress of AlOₓ is intentionally made to come to the positive side or the negative side.

The base layer 10 can be used as a barrier layer against external moisture and the like. An AlOₓ film is different in quality depending on moisture pressure during sputtering and a denser film can be obtained with decrease in moisture pressure. The denser a film is, the higher the barrier property against moisture and the like can be made.

There is a correlation between the denseness of an AlOₓ film and the refraction index of the AlOₓ film The denser a film is, the higher the refraction index of the AlOₓ film is. FIG. 10 is a graph indicating a relation between moisture pressure during AlOₓ sputtering and the refraction index of deposited AlOₓ. That is, the quality of an AlOₓ film can be evaluated by measuring the refraction index of deposited AlOₓ. In FIG. 9 and FIG. 10, the symbols of circle, triangle, cross, and the like indicate that the formed samples are different in lot.

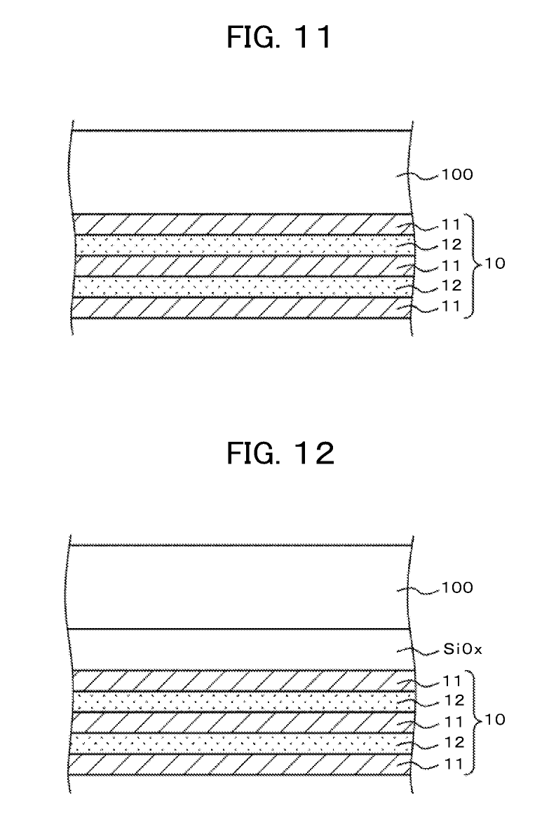

In the present invention, the laminated structure shown in FIG. 11 can be used. In this laminated structure, first AlOₓ 11, high in barrier property, sputtered at a low moisture pressure and second AlOₓ 12 sputtered at a higher moisture pressure than for the first AlOₓ are used. This makes it possible to maintain an excellent barrier property and form a base layer 10 whose membrane stress is arbitrarily controlled and this is one of the features of the present invention. In the example in FIG. 11, the first AlOₓ 11 is, for example, 10 nm and the second AlOₓ 12 is, for example, 10 nm.

More specific description will be given. The second AlOₓ 12 can be provided with a membrane stress having an opposite sign to that of the first AlOₓ 11; therefore, it is also possible to reduce the membrane stress of the entire laminated film of the first AlOₓ 11 and the second AlOₓ 12. Meanwhile, since the first AlOₓ 11 has a high barrier property, the entire base layer can be provided with a high barrier property.

For example, as indicated in FIG. 9, the moisture pressure is set to approximately P1 (9×10⁻⁶ Pa) when the first AlOₓ is formed and the moisture pressure is set to approximately P2 (4×10⁻⁴ Pa) when the second AlOₓ is formed. As a result, the membrane stress of the first AlOₓ 11 is approximately −200 MPa and that of the second AlOₓ 12 is approximately 180 MPa. That, for the entire first base layer 10, a very low membrane stress can be obtained. Further, it is also possible to form a base layer high in tensile strength or compressive strength as required.

FIG. 11 illustrates an example in which the base layer 10 is formed of only AlOₓ different in film quality. There are also cases where, as shown in FIG. 12, SiOₓ ought to be placed between the AlOₓ layer 10 and the polyimide substrate 100 because of compatibility with the polyimide substrate 100 or the like. Rather than only SiOₓ, a laminated film of SiOₓ and SiNₓ may be placed between the AlOₓ layer 10 and the polyimide substrate 100. The film thickness of SiOₓ or SiNₓ is, for example, 50 nm to 300 nm. Further, SiOₓ or SiNₓ may be formed between the AlOₓ layer 10 and the first glass substrate 1. In this case, in products, SiOₓ or SiNₓ is placed outside AlOₓ.

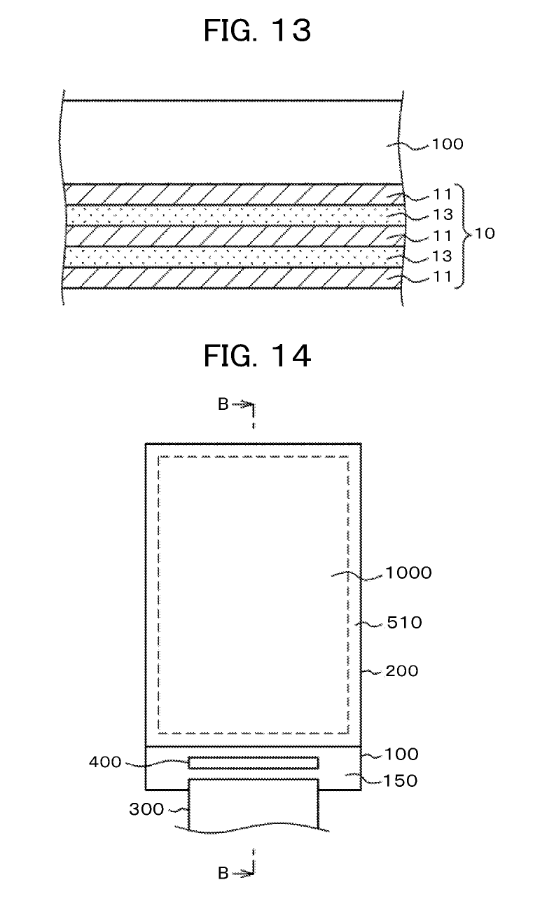

FIG. 11 illustrates a case where the base layer 10 is formed of a laminated film of AlOₓ 11 and AlOₓ 12 different in film quality. Instead, as illustrated in FIG. 13, the base layer 10 may be formed of a laminated film of AlOₓ 11 and Al 13. Since Al 13 is softer and lower in membrane stress than AlOₓ 11, it can be used to control the membrane stress of the base layer 10. Al 13, together with AlOₓ 11, can also be caused to function as a barrier against external moisture and the like. However, the configuration including Al 13, shown in FIG. 13, does not pass light and thus it is difficult to use it as a base layer on the opposite substrate 200.

The TFT in FIG. 7 is configured as a so-called top gate-type TFT in which a gate electrode is present above a semiconductor layer. The present invention can also be completely similarly applicable to a bottom gate-type TFT in which a semiconductor layer is present above a gate electrode.

To enhance a barrier function, a base layer containing AlOₓ may be provided between a polyimide substrate and TFT, between TFT and an organic passivation film, between the protective layer 114 and an adhesive material, or the like. This makes it possible to increase the effects of barrier performance enhancement and flexible substrate warping prevention.

### Second Embodiment

Liquid crystal display devices can also be made as a flexible display by thinning a TFT substrate or an opposite substrate. As described in relation to the first embodiment with reference to FIGS. 6A to 6E, a TFT substrate and an opposite substrate can also be formed of such resin as polyimide.

FIG. 14 is a plan view of a liquid crystal display device. In the example in FIG. 14, a display area 1000 is formed in an opposite substrate 200 opposed to a TFT substrate 100 and an upper polarizing plate 510 is placed so as to cover the display area 1000. A terminal part 150 has a driver IC 400 and a flexible wiring board 300 connected thereto.

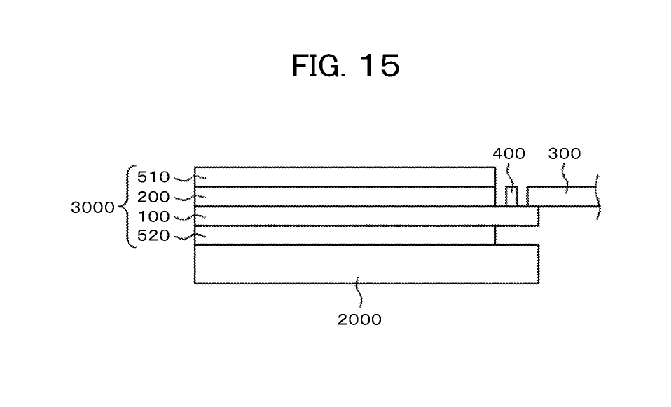

FIG. 15 is a sectional view taken along line B-B of FIG. 14. In FIG. 15, the TFT substrate 100 and the opposite substrate 200 are disposed opposite to each other and a liquid crystal is sandwiched between the TFT substrate 100 and the opposite substrate 200. An upper polarizing plate 510 is bonded onto the opposite substrate 200 and a lower polarizing plate 520 is bonded to the underside of the TFT substrate 100. The TFT substrate 100, the opposite substrate 200, the upper polarizing plate 510, and the lower polarizing plate 520 constitute a liquid crystal display panel 3000. A backlight 2000 is disposed under the lower polarizing plate 520.

In FIG. 15, the liquid crystal display panel 3000 can be provided with a flexibly bendable structure by forming the TFT substrate 100 or the opposite substrate 200 of a thin resin or glass material. The backlight 2000 includes a light source, a light guide plate, an optical sheet, and the like. The backlight can also be made flexible and the entire liquid crystal display device can be configured as a flexible display device by forming the light guide plate of a thin resin material or taking other like means.

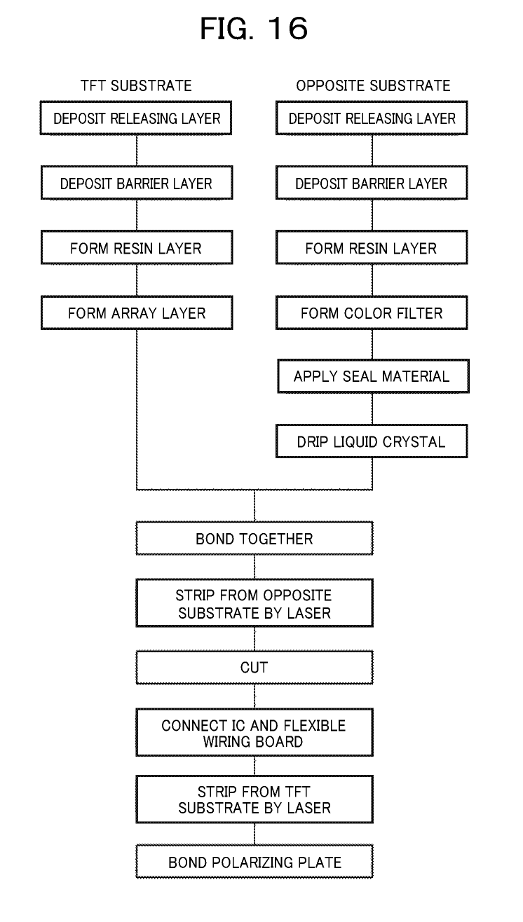

FIG. 16 illustrates an example of a manufacturing process for such a liquid crystal display device. Also in case of liquid crystal display devices, as shown in FIG. 4, they are first formed in a mother substrate like the case of the organic EL display device. In the example in FIG. 16, a TFT substrate and an opposite substrate are separately formed and after a liquid crystal is dripped onto the opposite substrate side, the substrates are bonded together.

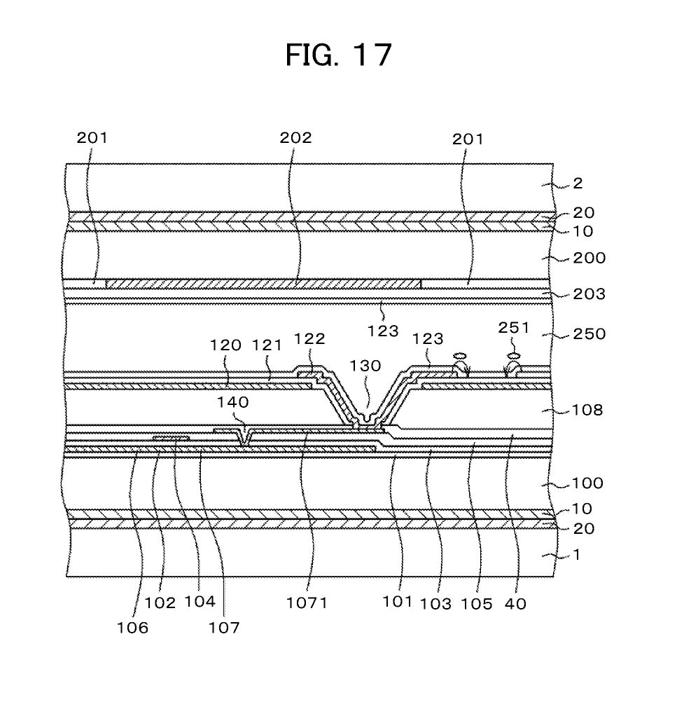

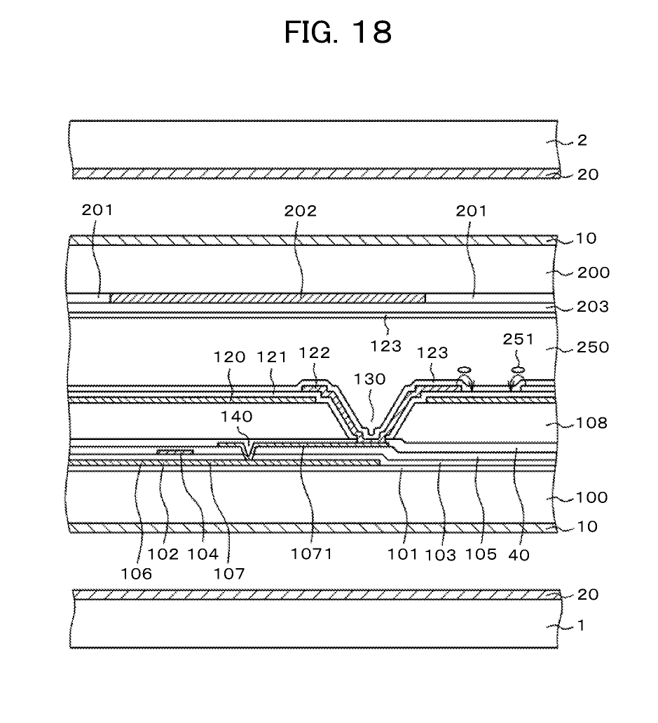

The method of forming the TFT substrate and opposite substrate of polyimide shown in FIG. 16 is the same as that for the organic EL display device described with reference to FIG. 5 and FIGS. 6A to 6E. After the formation of polyimide substrates, an array layer is formed on the TFT substrate side. On the opposite substrate side, meanwhile, a color filter and a seal material are formed and a liquid crystal is dripped. The configurations of the TFT substrate side and the opposite substrate side will be described in detail with reference to FIG. 17.

In the example in FIG. 16, the TFT substrate and the opposite substrate are bonded together and then the glass substrate is stripped first from the opposite substrate side by laser ablation. Thereafter, the substrates are cut into individual liquid crystal cells and a driver IC and a flexible wiring board are connected to each liquid crystal cell. Thereafter, the glass substrate is stripped from the TFT substrate side by laser ablation. Thereafter, a lower polarizing plate and an upper polarizing plate are respectively bonded to the TFT substrate side and the opposite substrate side.

FIG. 17 is a sectional view of the display area with the TFT substrate 100 side and the opposite substrate 200 bonded together by the processing of FIG. 16. In FIG. 17, a releasing layer 20 is formed on a first glass substrate 1 and a base layer 10 is formed thereon. The TFT substrate 100 is formed thereon of polyimide. This process is the same as that for the organic EL display device described with reference to FIGS. 6A to 6E.

A base film 101 is formed of SiOₓ or SiNₓ on the TFT substrate 100. The configuration of the TFT formed on the base film 101 is basically the same as the configuration described in relation to the first embodiment with reference to FIG. 7. That is, a semiconductor layer 102 is formed on the first base layer 10 and a gate insulating film 103 of SiOₓ formed of TEOS covers the same. A gate electrode 104 is formed on the gate insulating film 103 and an interlayer insulating film 105 of SiNₓ formed by sputtering is formed so as to cover the same.

A contact electrode 1071 is formed on the interlayer insulating film 105. The contact electrode 1071 is connected with the drain electrode 107 of the TFT via a through hole 140 and connected with a pixel electrode 122 via a through hole 130. A drain electrode 106 in FIG. 17 is connected with a video signal line. In the example in FIG. 17, an inorganic passivation film 40 of, for example, SiNₓ is formed on the interlayer insulating film 105. The inorganic passivation film 40 protects the TFT against moisture and hydrogen entering from above.

An organic passivation film 108 also functioning as a planarization film is formed on the inorganic passivation film 40. A planar common electrode 120 is formed on the organic passivation film 108, a capacitance insulating film 121 is formed thereon, and a pixel electrode 122 is formed thereon. The pixel electrode 122 is connected with the contact electrode 1071 via the through hole 130. The capacitance insulating film 121, together with the pixel electrode 122 and the common electrode 120, constitutes a holding capacitor. In the example in FIG. 17, when a voltage is applied to the pixel electrode 122, such electric lines of force as indicated by arrows are produced between the pixel electrode and the common electrode 120, driving liquid crystal molecules 251. An orientation film 123 is formed on the pixel electrode 122 for initially orienting liquid crystal molecules 251.

In FIG. 17, an opposite substrate 200 is opposed to the TFT substrate with a liquid crystal layer 250 in between. The opposite substrate 200 is also formed of polyimide. The method for forming the opposite substrate 200 is the same as that for the TFT substrate 100 and is as described with reference to FIG. 16 and FIGS. 6A to 6E. That is, a releasing layer 20 is formed on a second glass substrate 2, a base layer 10 is formed thereon, and a polyimide substrate to be the opposite substrate 200 is formed thereon.

A black matrix 202 and a color filter 201 are formed on the opposite substrate 200 and an overcoat film 203 is formed so as to cover the color filter 201. An orientation film 123 is formed so as to cover the overcoat film 203 for initially orienting liquid crystal molecules 251.

Thereafter, as shown in FIG. 18, the second glass substrate 2 is first stripped from the opposite substrate 2 by laser ablation. As the result of this laser ablation, the releasing layer 2 is stripped off together with the second glass substrate 2 and the base layer 10 is left outside the opposite substrate 200.

Thereafter, the mother substrates are cut and separated into individual liquid crystal cells and a driver IC and a flexible wiring board are connected thereto. Thereafter, as shown in FIG. 18, the first glass substrate 1 is stripped from the TFT substrate 100 side by laser ablation. The releasing layer 20 is stripped off together with the first glass substrate 1 and the base layer 10 still exists outside the TFT substrate 100.

As described above, also in case of the liquid crystal display device, the base layer 10 can be left outside the TFT substrate 100 or the opposite substrate 200 formed of polyimide. This makes it possible to prevent damage to the polyimide substrates 100, 200 during laser ablation. As described with reference to FIG. 11 and FIG. 12, it is possible to control membrane stress and prevent a warp in the flexible display device by forming the base layer 10 as a multilayer film containing AlOₓ.

When a base layer includes an Al layer as shown in FIG. 13, the base layer is opaque; therefore, it is difficult to use it in a liquid crystal display device having a backlight. However, it is applicable to a reflection-type liquid crystal display device.

The TFT in FIG. 17 is configured as a so-called top gate-type TFT in which a gate electrode is present above a semiconductor layer. The present invention is completely similarly applicable to a bottom gate-type TFT with no problems in which TFT a semiconductor layer is present above a gate electrode.

To enhance a barrier function, a base layer containing AlOₓ may be provided between the TFT substrate 100 and TFT, between TFT and the organic passivation film 108, between the opposite substrate 200 and the color filter or the black matrix, and the like. This makes it possible to increase the effects of barrier performance enhancement and flexible substrate warping prevention.

What is claimed is:

1. An organic EL display device in which TFT is formed in a first substrate and an organic EL layer is formed on the TFT,
wherein a protective layer is formed on the organic EL layer, and
wherein a first base layer is formed outside the first substrate.

2. The organic EL display device according to claim 1,
wherein the first base layer is formed of a layer containing AlOₓ.

3. The organic EL display device according to claim 1,
wherein the first base layer is of a laminated structure of first AlOₓ and second AlOₓ different in film quality.

4. The organic EL display device according to claim 1,
wherein a second substrate is formed on the protective layer, and
wherein a second base layer is formed outside the second substrate.

5. The organic EL display device according to claim 4,
wherein the second base layer is formed of a layer containing AlOₓ.

6. A method for manufacturing an organic EL display device in which TFT is formed in a first substrate and an organic EL layer is formed on the TFT, comprising:
forming a releasing layer on a first glass substrate;
forming a base layer on the releasing layer;
forming a first substrate of polyimide on the base layer;
forming the TFT in the first substrate and forming an organic EL layer on the TFT;
forming a protective layer on the organic EL layer; and
thereafter, stripping the glass substrate, together with the releasing layer, from the first substrate.

7. The method for manufacturing an organic EL display device according to claim 6,
wherein the releasing layer is formed of metal, such as Ti, Ni, Cu, Fe, Ag, Au, Cr, Mo, and W or an alloy containing these metals.

8. The method for manufacturing an organic EL display device according to claim 6,
wherein the base layer is formed of AlOₓ.

9. The method for manufacturing an organic EL display device according to claim 6,
wherein the base layer is formed in a laminated structure of first AlOₓ under a first moisture pressure and second AlOₓ under a second moisture pressure.

10. The method for manufacturing an organic EL display device according to claim 6,
wherein the stripping is carried out by laser ablation.

11. A liquid crystal display device comprising:
TFT and a pixel electrode formed in a first substrate;
an opposite substrate disposed opposite to the first substrate; and
a liquid crystal sandwiched between the first substrate and the second substrate,
wherein a first base layer is formed outside the first substrate.

12. The liquid crystal display device according to claim 11,
wherein the first base layer is formed of a layer containing AlOₓ.

13. The liquid crystal display device according to claim 11,
wherein the first base layer is of a laminated structure of first AlOₓ and second AlOₓ different in film quality.

14. The liquid crystal display device according to claim 11,
wherein a second base layer is formed outside the second substrate.

15. The liquid crystal display device according to claim 14,
wherein the second base layer is formed of a layer containing AlOₓ.
